(19) United States
(12) Patent Application Publication
(10) Pub. No.: US 2021/0175403 A1
(43) Pub. Date: Jun. 10, 2021

(54) THERMOELECTRIC MODULE

(71) Applicants: HYUNDAI MOTOR COMPANY, Seoul (KR); KIA MOTORS CORPORATION, Seoul (KR)

(72) Inventors: Woo Ju Lee, Seoul (KR); Min Jae Lee, Seoul (KR); Hoo Dam Lee, Seongnam-si (KR); Byung Wook Kim, Seongnam-si (KR)

(21) Appl. No.: 16/801,503

(22) Filed: Feb. 26, 2020

(30) Foreign Application Priority Data
Dec. 9, 2019 (KR) 10-2019-0162817

(51) Int. Cl. H01L 35/32; H01C 7/04

(52) U.S. Cl. CPC H01L 35/32; H01C 7/04

(57) ABSTRACT

A thermoelectric module is disclosed. The thermoelectric module includes a first thermoelectric material unit, a second thermoelectric material unit connected in series to the first thermoelectric material unit, and a bypass circuit connected in parallel to the first thermoelectric material unit and the second thermoelectric material unit and configured to selectively divert current that is applied to the first thermoelectric material unit to the second thermoelectric material unit, thereby obtaining advantageous effects of improved stability and reliability.

### CROSS REFERENCE TO RELATED APPLICATIONS

This application claims the priority benefit of Korean Patent Application No. 10-2019-0162817, filed on Dec. 9, 2019 in the Korean Intellectual Property Office, the disclosure of which is incorporated herein by reference.

### BACKGROUND

### 1. Field

The present disclosure relates to a thermoelectric module, and more particularly to a thermoelectric module capable of performing local temperature control in response to pressure and improving energy efficiency.

### 2. Description of the Related Art

A thermoelectric device is a device that converts thermal energy into electrical energy or vice versa, and is also called a thermoelectric module, a Peltier module, a thermoelectric cooler (TEC), etc. Such a thermoelectric device is widely used as a cooling device or a heating device using the Peltier effect, in which, when electric current is passed through a circuit consisting of two different conductors, a cooling effect is observed at one junction whereas another junction experiences a rise in temperature.

In general, a thermoelectric module is configured such that a plurality of thermoelectric materials (e.g. a P-type thermoelectric material and an N-type thermoelectric material) is connected in series (in the form of a series circuit) on a substrate, and has advantages of low heat loss and rapid temperature control.

However, in the conventional thermoelectric module, in which a plurality of thermoelectric materials is connected in series, when an open circuit occurs in any one of the plurality of thermoelectric materials, the entire thermoelectric module becomes nonfunctional.

Therefore, in recent years, various studies have been conducted to enable a thermoelectric module to operate in spite of the occurrence of an open circuit in thermoelectric materials, but results thereof are insufficient, and there is thus the need for development thereof.

### SUMMARY

Therefore, the present disclosure has been made in view of the above problems, and it is an object of the present disclosure to provide a thermoelectric module having improved stability and reliability.

It is another object of the present disclosure to provide a thermoelectric module capable of operating in spite of the occurrence of an open circuit in a thermoelectric material.

It is a further object of the present disclosure to provide a thermoelectric module having improved performance and a prolonged lifespan.

In accordance with an aspect of the present disclosure, the above and other objects can be accomplished by the provision of a thermoelectric module including a first thermoelectric material unit, a second thermoelectric material unit connected in series to the first thermoelectric material unit, and a bypass circuit connected in parallel to the first thermoelectric material unit and the second thermoelectric material unit and configured to selectively divert the current applied to the first thermoelectric material unit to the second thermoelectric material unit.

This configuration is for improving the stability and reliability of the thermoelectric module.

That is, in the conventional art, because a plurality of thermoelectric materials constituting a thermoelectric module is connected in series to each other, when an open circuit occurs in any one of the plurality of thermoelectric materials, the entire thermoelectric module becomes nonfunctional.

However, according to the present disclosure, since the current that is applied to the first thermoelectric material unit is selectively diverted to the second thermoelectric material unit, even when an electrical problem (e.g. an open circuit) occurs in the first thermoelectric material unit, the remaining second thermoelectric material unit, excluding the first thermoelectric material unit, may operate normally, thereby obtaining advantageous effects of improved stability and reliability.

According to the embodiment of the present disclosure, the first thermoelectric material unit may be composed of one first unit thermoelectric material, or may be composed of a group including a plurality of first unit thermoelectric materials connected in series to each other.

In one example, the first unit thermoelectric material may include one first N-type thermoelectric material and one first P-type thermoelectric material. According to another embodiment of the present disclosure, the first unit thermoelectric material may be composed of any one of the first N-type thermoelectric material and the first P-type thermoelectric material.

According to the embodiment of the present disclosure, the second thermoelectric material unit may be composed of one second unit thermoelectric material, or may be composed of a group including a plurality of second unit thermoelectric materials connected in series to each other.

In one example, the second unit thermoelectric material may include one second N-type thermoelectric material and one second P-type thermoelectric material. According to another embodiment of the present disclosure, the second unit thermoelectric material may be composed of any one of the second N-type thermoelectric material and the second P-type thermoelectric material.

Preferably, one end of the bypass circuit may be connected to an input terminal of the first thermoelectric material unit, and the other end of the bypass circuit may be connected to an input terminal of the second thermoelectric material unit.

In one example, the bypass circuit may include a resistor configured such that the resistance value thereof decreases in accordance with a rise in temperature.

More specifically, when an open circuit occurs in the first thermoelectric material unit, the resistance value of the resistor may decrease, and the current that is applied to the first thermoelectric material unit may be diverted to the second thermoelectric material unit through the resistor.

More preferably, the resistor may be implemented as a negative temperature coefficient (NTC) thermistor, which is characterized in that the resistance value thereof decreases in accordance with a rise in temperature.

### BRIEF DESCRIPTION OF THE FIGURES

The above and other objects, features and other advantages of the present disclosure will be more clearly understood from the following detailed description taken in conjunction with the accompanying drawings, in which:

FIG. 1 is a diagram illustrating a thermoelectric module according to the present disclosure;

FIG. 2 is a diagram illustrating the flow of current when the thermoelectric module according to the present disclosure operates normally;

FIG. 3 is a diagram illustrating the flow of current when an open circuit occurs in the thermoelectric module according to the present disclosure;

FIG. 4 is a diagram illustrating a change in resistance of a resistor depending on a change in temperature;

FIGS. 5 and 6 are diagrams illustrating a first thermoelectric material unit and a second thermoelectric material unit of the thermoelectric module according to the present disclosure;

FIG. 7 is a mimetic diagram illustrating the flow of current through a plurality of thermoelectric material units when the thermoelectric module according to the present disclosure operates normally;

FIGS. 8 and 9 are mimetic diagrams illustrating the flow of current through a plurality of thermoelectric material units when an open circuit occurs in the thermoelectric module according to the present disclosure;

FIG. 10 is a mimetic diagram illustrating the flow of current through a plurality of thermoelectric material units when a thermoelectric module according to another embodiment of the present disclosure operates normally; and

FIGS. 11 and 12 are mimetic diagrams illustrating the flow of current through a plurality of thermoelectric material units when an open circuit occurs in the thermoelectric module according to another embodiment of the present disclosure.

### DETAILED DESCRIPTION

Hereinafter, the exemplary embodiments of the present disclosure will be described with reference to the accompanying drawings, but the present disclosure is not limited to the embodiments. For reference, in this description, the same reference numerals denote substantially the same elements, contents illustrated in different figures are referenced and described accordingly, and contents that are determined to be evident to those skilled in the art and that are repeated may be omitted.

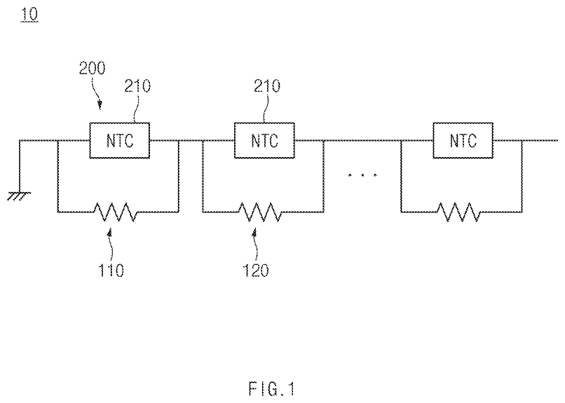

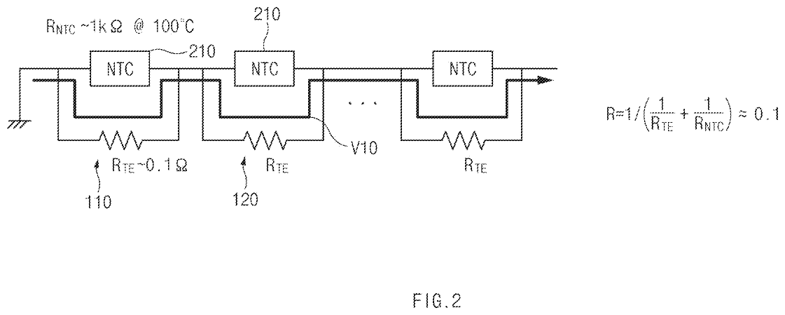

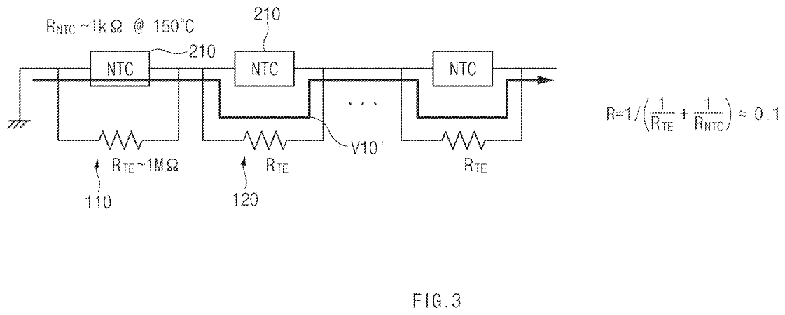

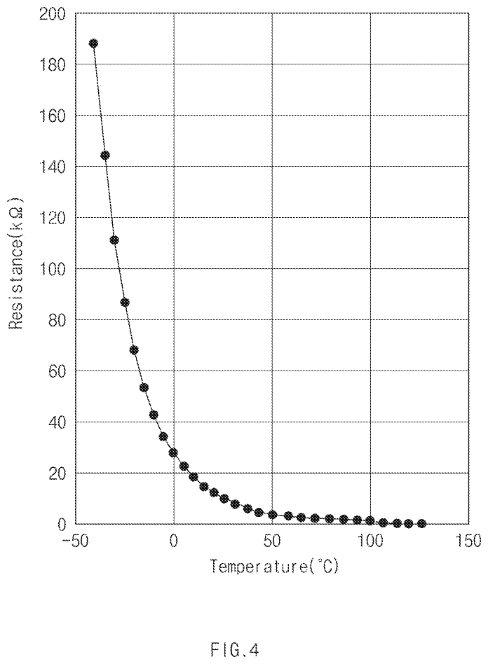

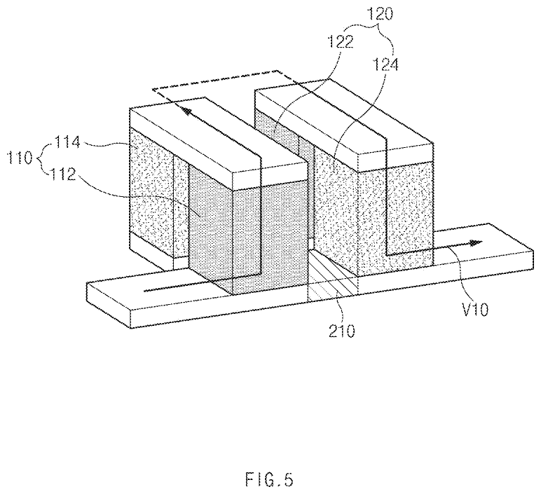

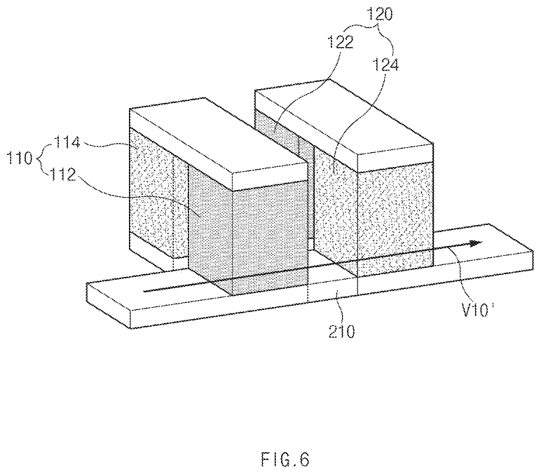

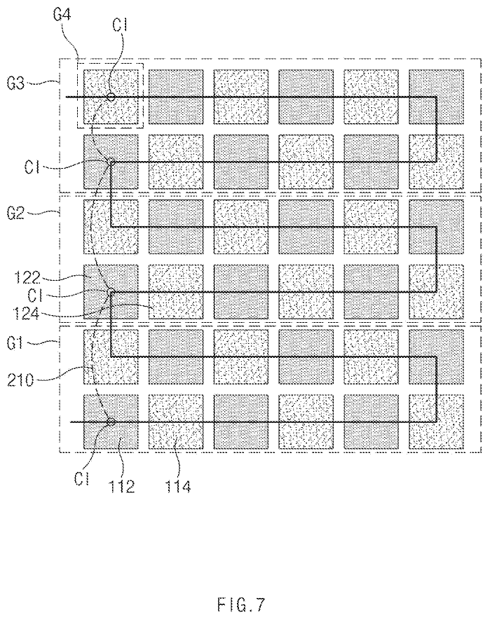

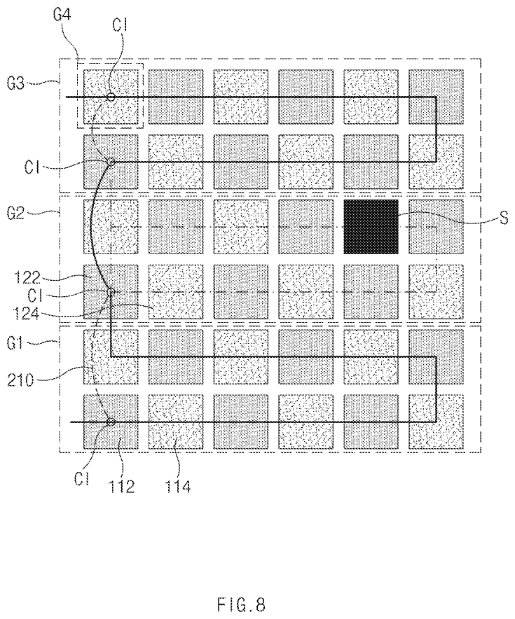

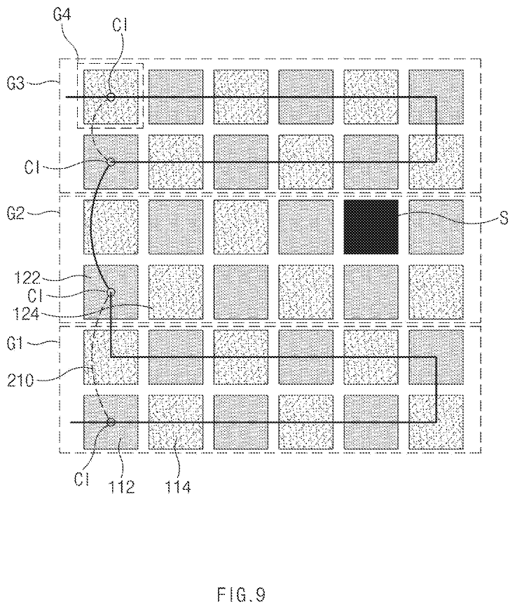

FIG. 1 is a diagram illustrating a thermoelectric module according to the present disclosure, FIG. 2 is a diagram illustrating the flow of current when the thermoelectric module according to the present disclosure operates normally, and FIG. 3 is a diagram illustrating the flow of current when an open circuit occurs in the thermoelectric module according to the present disclosure. FIG. 4 is a diagram illustrating a change in the resistance of a resistor depending on a change in temperature, and FIGS. 5 and 6 are diagrams illustrating a first thermoelectric material unit and a second thermoelectric material unit of the thermoelectric module according to the present disclosure. FIG. 7 is a mimetic diagram illustrating the flow of current through a plurality of thermoelectric material units when the thermoelectric module according to the present disclosure operates normally, and FIGS. 8 and 9 are mimetic diagrams illustrating the flow of current through a plurality of thermoelectric material units when an open circuit occurs in the thermoelectric module according to the present disclosure.

Referring to FIGS. 1 to 9, a thermoelectric module 10 according to the present disclosure includes a first thermoelectric material unit G1 (FIGS. 7-9), a second thermoelectric material unit G2 connected in series to the first thermoelectric material unit G1, and a bypass circuit 200 connected in parallel to the first thermoelectric material unit G1 and to the second thermoelectric material unit G2 in order to selectively divert the current that is applied to the first thermoelectric material unit G1 to the second thermoelectric material unit G2.

For reference, the thermoelectric module 10 includes a plurality of thermoelectric material units G1 to G3, which are disposed on a substrate (not shown). In one example, the first thermoelectric material unit G1, the second thermoelectric material unit G2, and the third thermoelectric material unit G3 may be arranged in a zigzag manner on the substrate so as to form a series circuit.

According to another embodiment of the present disclosure, the thermoelectric module may include two thermoelectric material units, or may include four or more thermoelectric material units. However, the present disclosure is not restricted or limited as to the number or arrangement of the thermoelectric material units.

The substrate is provided to maintain the shape of the thermoelectric module 10 and to protect the first thermoelectric material unit G1 and the second thermoelectric material unit G2 from the external environment.

The material and the structure of the substrate may be variously changed according to the required conditions and the use environment. The present disclosure is not restricted or limited as to the material or the structure of the substrate. In one example, the substrate may be made of a material that is flexible and has an electrical insulation property (e.g. silicon).

Referring to FIGS. 5 and 6, the first thermoelectric material unit G1 may be composed of one first unit thermoelectric material 110 (refer to G4 in FIG. 7), or may be composed of a group including a plurality of first unit thermoelectric materials 110, which are connected in series to each other. However, the present disclosure is not restricted or limited as to the number or arrangement of the first unit thermoelectric materials 110 constituting the first thermoelectric material unit G1.

Hereinafter, the configuration in which the first thermoelectric material unit G1 includes a plurality of first unit thermoelectric materials 110 connected in series will be described by way of example.

The plurality of first unit thermoelectric materials 110 is connected to form a series circuit, and is configured to simultaneously operate (perform heating or cooling) when electric power is supplied thereto from a power supply unit (not shown).

For reference, the first unit thermoelectric material 110 is a device that converts thermal energy into electrical energy or vice versa, and is also called a Peltier module, a thermoelectric cooler (TEC), etc. It is widely used as a cooling device or a heating device using the Peltier effect, in which, when electric current is passed through a circuit consisting of two different conductors, a cooling effect is observed at one junction whereas another junction experiences a rise in temperature.

In one example, the first unit thermoelectric material 110 may include one first N-type thermoelectric material 112 and one first P-type thermoelectric material 114, which have opposite polarities to each other. According to another embodiment of the present disclosure, the first unit thermoelectric material may be composed of only one of the first N-type thermoelectric material and the first P-type thermoelectric material.

More specifically, first unit thermoelectric materials 110 that are adjacent to each other may be connected to each other to form a series circuit via a first electrode (not shown) connected to one end of each first unit thermoelectric material 110 and a second electrode (not shown) connected to the other end of each first unit thermoelectric material 110.

Referring to FIGS. 5 and 6, the second thermoelectric material unit G2 may be composed of one second unit thermoelectric material 120 (refer to G4 in FIG. 7), or may be composed of a group including a plurality of second unit thermoelectric materials 120, which are connected in series to each other. However, the present disclosure is not restricted or limited as to the number or arrangement of the second unit thermoelectric materials 120 constituting the second thermoelectric material unit G2.

Hereinafter, the configuration in which the second thermoelectric material unit G2 includes a plurality of second unit thermoelectric materials 120 connected in series will be described by way of example.

The plurality of second unit thermoelectric materials 120 is connected to form a series circuit, and is configured to simultaneously operate (perform heating or cooling) when electric power is supplied thereto from the power supply unit (not shown).

For reference, the second unit thermoelectric material 120 is a device that converts thermal energy into electrical energy or vice versa, and is also called a Peltier module, a thermoelectric cooler (TEC), etc. It is widely used as a cooling device or a heating device using the Peltier effect, in which, when electric current is passed through a circuit consisting of two different conductors, a cooling effect is observed at one junction whereas another junction experiences a rise in temperature.

In one example, the second unit thermoelectric material 120 may include one second N-type thermoelectric material 122 and one second P-type thermoelectric material 124, which have opposite polarities to each other. According to another embodiment of the present disclosure, the second unit thermoelectric material may be composed of only one of the second N-type thermoelectric material and the second P-type thermoelectric material.

More specifically, second unit thermoelectric materials 120 that are adjacent to each other may be connected to each other to form a series circuit via a first electrode (not shown) connected to one end of each second unit thermoelectric material 120 and a second electrode (not shown) connected to the other end of each second unit thermoelectric material 120.

In the same manner, the third thermoelectric material unit G3 may be composed of one third unit thermoelectric material (not shown), or may include a plurality of third unit thermoelectric materials, which are connected in series to each other. However, the present disclosure is not restricted or limited as to the number or arrangement of the third unit thermoelectric materials constituting the third thermoelectric material unit G3.

The bypass circuit 200 is connected in parallel to the first to third thermoelectric material units G1 to G3, and is configured to selectively divert the current that is applied to the first thermoelectric material unit G1 to the second thermoelectric material unit G2 or to selectively divert the current that is applied to the second thermoelectric material unit G2 to the third thermoelectric material unit G3.

This configuration is for preventing a problem in which, when an open circuit occurs in any one of the plurality of unit thermoelectric materials constituting the first to third thermoelectric material units G1 to G3, the entire thermoelectric module 10 becomes nonfunctional.

That is, in the conventional art, because a plurality of thermoelectric materials constituting a thermoelectric module is connected in series, when an open circuit occurs in any one of the plurality of thermoelectric materials, the entire thermoelectric module becomes nonfunctional.

However, according to the present disclosure, since the current that is applied to the first thermoelectric material unit G1 is selectively diverted to the second thermoelectric material unit G2, or since the current that is applied to the second thermoelectric material unit G2 is selectively diverted to the third thermoelectric material unit G3, even when an electrical problem (e.g. an open circuit) occurs in the first thermoelectric material unit G1 (or the second thermoelectric material unit), the remaining second thermoelectric material unit G2 (or the third thermoelectric material unit), excluding the first thermoelectric material unit G1 (or the second thermoelectric material unit), may operate normally, thereby obtaining advantageous effects of improved stability and reliability.

More specifically, one end of the bypass circuit 200 is connected to an input terminal (refer to CI in FIG. 7) of the first thermoelectric material unit G1, and the other end of the bypass circuit 200 is connected to an input terminal CI of the second thermoelectric material unit G2.

Here, the input terminal CI of the first thermoelectric material unit G1 is defined as the point through which current is applied to the first thermoelectric material unit G1, and the input terminal CI of the second thermoelectric material unit G2 is defined as the point through which current is applied to the second thermoelectric material unit G2.

The bypass circuit 200 may be implemented as any of various devices, so long as it is capable of selectively diverting the current that is applied to the first thermoelectric material unit G1 to the second thermoelectric material unit G2 (or selectively diverting the current that is applied to the second thermoelectric material unit G2 to the third thermoelectric material unit G3). However, the present disclosure is not restricted or limited as to the type or the characteristics of the bypass circuit 200.

In one example, the bypass circuit 200 may include a resistor 210, which has a characteristic in which the resistance value thereof decreases in accordance with a rise in temperature.

More specifically, when an open circuit (refer to S in FIG. 8) occurs in the first thermoelectric material unit G1, current flows through the resistor 210, which is connected in parallel to the first thermoelectric material unit G1, and Joule heat is thus generated. Accordingly, the structure and the properties of the resistor 210 are changed, and the resistance value of the resistor 210 decreases. Due to the decrease in the resistance value of the resistor 210, the current that is applied to the first thermoelectric material unit G1 may be diverted to the second thermoelectric material unit G2 through the resistor 210.

In the same manner, when an open circuit occurs in the second thermoelectric material unit G2, current flows through the resistor 210, which is connected in parallel to the second thermoelectric material unit G2, and Joule heat is thus generated. Accordingly, the structure and the properties of the resistor 210 are changed, and the resistance value of the resistor 210 decreases. Due to the decrease in the resistance value of the resistor 210, the current that is applied to the second thermoelectric material unit G2 may be diverted to the third thermoelectric material unit G3 through the resistor 210.

Preferably, a negative temperature coefficient (NTC) thermistor, which is characterized in that the resistance value thereof decreases in accordance with a rise in temperature, is used as the resistor 210.

For reference, referring to FIG. 4, it can be seen that the resistance value of the resistor 210 (the NTC thermistor) decreases in accordance with a rise in temperature.

Hereinafter, the flow of current during the normal operation of the thermoelectric module 10 and the flow of current in the event of an open circuit in the thermoelectric module 10 will be described with reference to FIGS. 2, 3 and 5 to 9.

Referring to FIGS. 2, 5 and 7, when the thermoelectric module 10 operates normally (in the state in which the resistance value of the NTC thermistor 210 is not less than a predetermined reference value), the resistance value R_{NTC} of the NTC thermistor 210 is much greater than the resistance value R_{TE} of the first unit thermoelectric material 110. Thus, most of the current V10 that is applied to the first thermoelectric material unit G1 flows through the first unit thermoelectric material 110. Similarly, most of the current V10 that is applied to the second thermoelectric material unit G2 flows through the second unit thermoelectric material 120.

In this case, since the NTC thermistor 210 is connected in parallel to the first to third thermoelectric material units G1 to G3, the total resistance value R of the thermoelectric module 10 approximates the resistance value (e.g. about 0.1Ω) of the first unit thermoelectric material 110 (or the second unit thermoelectric material).

For reference, it can be understood that the flow of current indicated by the dotted lines is the flow of current that passes through the first P-type thermoelectric material 114 of the first unit thermoelectric material 110 and the second N-type thermoelectric material 122 of the second unit thermoelectric material 120.

On the other hand, as shown in FIGS. 3, 6 and 9, when an open circuit S occurs in any one of the unit thermoelectric materials, any one of the electrodes, or the like in the thermoelectric module 10, for example, when an open circuit S occurs in the first unit thermoelectric material 110 (or the second unit thermoelectric material) constituting the first thermoelectric material unit G1 (or the second thermoelectric material unit), current is forcibly passed through the NTC thermistor 210, which is connected in parallel to the first thermoelectric material unit G1 (or the second thermoelectric material unit G2), and Joule heat is thus generated. Accordingly, the resistance value of the NTC thermistor 210 decreases (refer to FIG. 8). Due to the decrease in the resistance value of the NTC thermistor 210, the current V10′ that is applied to the first thermoelectric material unit G1 (or the second thermoelectric material unit) may be diverted to the second thermoelectric material unit G2 (or the third thermoelectric material unit) through the NTC thermistor 210.

In this case, in spite of the occurrence of an open circuit S in the thermoelectric module 10, the total resistance value R of the thermoelectric module 10 may be maintained at an appropriate level (e.g. about 0.1Ω).

When an open circuit S occurs in the first thermoelectric material unit G1 (or the second thermoelectric material unit) of the thermoelectric module 10, the first thermoelectric material unit G1 (or the second thermoelectric material unit G2) becomes nonfunctional, but the second thermoelectric material unit G2 (or the first thermoelectric material unit) and the third thermoelectric material unit G3 may operate normally.

Meanwhile, in the state in which an open circuit temporarily occurs in the thermoelectric module 10, when the resistance value of the unit thermoelectric material (or the thermoelectric material unit) decreases (returns) to a normal level (e.g. about 0.1Ω), current does not flow to the NTC thermistor 210, and thus the resistance value of the NTC thermistor 210 returns to the initial level (R_{NTC}>R_{TE}). As a result, most of the current V10 that is applied to the first thermoelectric material unit G1 (or the second thermoelectric material unit) flows again through the first unit thermoelectric material 110 (or the second unit thermoelectric material 120)

As described above, since the resistance value of the NTC thermistor 210 varies depending on whether there is an open circuit in the unit thermoelectric material of the thermoelectric module 10, the total resistance value R of the thermoelectric module 10 may be maintained at an appropriate level.

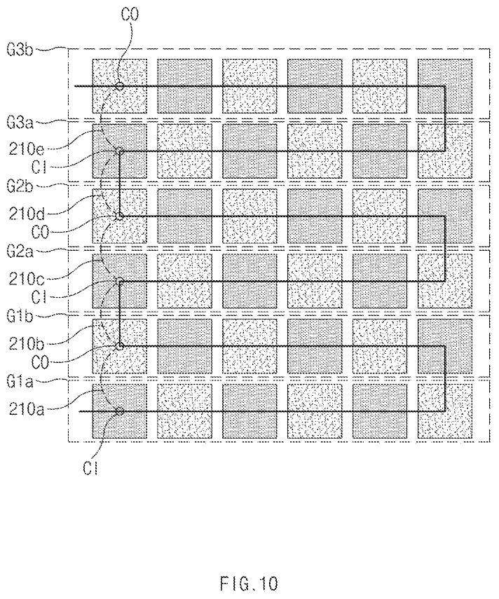

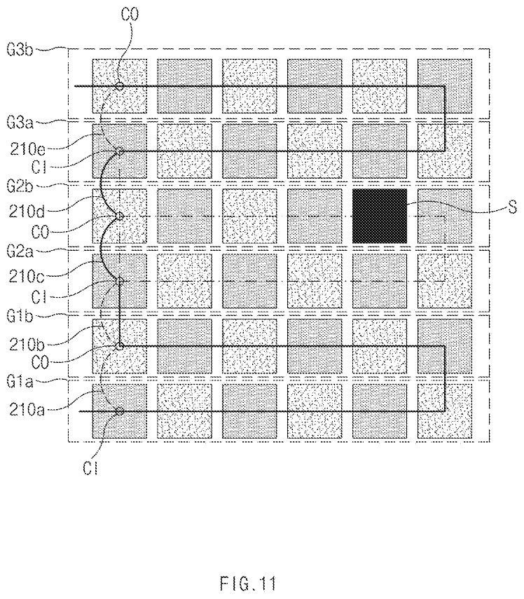

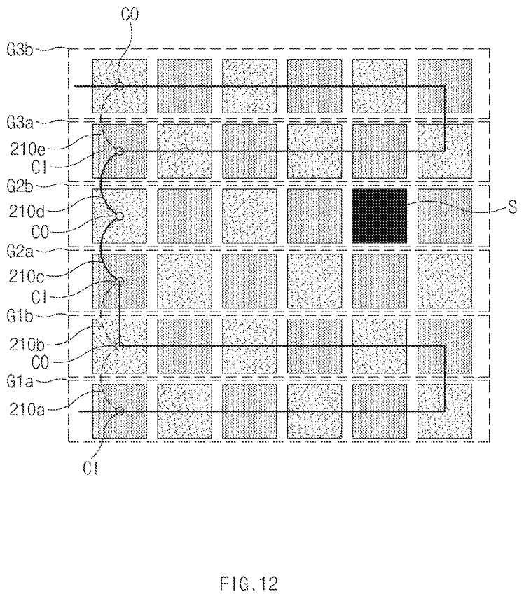

Meanwhile, each of the first to third thermoelectric material units G1 to G3 shown in FIG. 7 includes two rows composed of thermoelectric materials 112, 114, 122 and 124. However, the thermoelectric material units may be modified as shown in FIG. 10. Each of the thermoelectric material units G1a to G3b shown in FIG. 10 includes only one row of thermoelectric materials. Even in this case, the fundamental operation is the same as the above-described operation. When an open circuit S occurs, current is diverted through two NTC thermistors 210b and 210c among a plurality of NTC thermistors 210a to 210e.

One end of the bypass circuit 200 or one end of each of the NTC thermistors 210a, 210c and 210e may be connected to an input terminal CI of a respective one of the thermoelectric material units G1a, G2a and G3a, and the other end of the bypass circuit 200 or the other end of each of the NTC thermistors 210a, 210c and 210e may be connected to an output terminal CO of a respective one of the other thermoelectric material units G1b, G2b and G3b connected in series. Further, one end of the bypass circuit 200 or one end of each of the NTC thermistors 210b and 210d may be connected to an output terminal CO of a respective one of the thermoelectric material units G1b and G2b, and the other end of the bypass circuit 200 or the other end of each of the NTC thermistors 210b and 210d may be connected to an input terminal CI of a respective one of the other thermoelectric material units G2a and G3a connected in series.

As is apparent from the above description, the present disclosure provides a thermoelectric module having improved stability and reliability.

In particular, even when an open circuit occurs in a thermoelectric material, it is possible to prevent the entire thermoelectric module from being disabled and to enable the thermoelectric module to continuously work.

In addition, the thermoelectric module according to the present disclosure has improved performance and a prolonged lifespan.

Although the embodiments of the present disclosure have been disclosed for illustrative purposes, those skilled in the art will appreciate that various modifications, additions and substitutions are possible, without departing from the scope and spirit of the invention as disclosed in the accompanying claims.

1. A thermoelectric module, comprising:
a first thermoelectric material unit;
a second thermoelectric material unit connected in series to the first thermoelectric material unit; and
a bypass circuit connected in parallel to the first thermoelectric material unit and the second thermoelectric material unit, the bypass circuit being configured to selectively divert current that is applied to the first thermoelectric material unit to the second thermoelectric material unit.

2. The thermoelectric module according to claim 1, wherein the first thermoelectric material unit comprises one first unit thermoelectric material.

3. The thermoelectric module according to claim 2, wherein the first unit thermoelectric material comprises at least one of a first N-type thermoelectric material or a first P-type thermoelectric material.

4. The thermoelectric module according to claim 1, wherein the first thermoelectric material unit comprises a plurality of first unit thermoelectric materials connected in series to each other.

5. The thermoelectric module according to claim 4, wherein the first unit thermoelectric material comprises at least one of a first N-type thermoelectric material or a first P-type thermoelectric material.

6. The thermoelectric module according to claim 1, wherein the second thermoelectric material unit comprises one second unit thermoelectric material.

7. The thermoelectric module according to claim 6, wherein the second unit thermoelectric material comprises at least one of a second N-type thermoelectric material or a second P-type thermoelectric material.

8. The thermoelectric module according to claim 1, wherein the second thermoelectric material unit comprises a plurality of second unit thermoelectric materials connected in series to each other.

9. The thermoelectric module according to claim 8, wherein the first unit thermoelectric material comprises at least one of a first N-type thermoelectric material or a first P-type thermoelectric material.

10. The thermoelectric module according to claim 1, wherein one end of the bypass circuit is connected to an input terminal of the first thermoelectric material unit, and another end of the bypass circuit is connected to an input terminal of the second thermoelectric material unit.

11. The thermoelectric module according to claim 10, wherein the bypass circuit comprises a resistor configured such that a resistance value thereof decreases in accordance with a rise in temperature.

12. The thermoelectric module according to claim 11, wherein, when an open circuit occurs in the first thermoelectric material unit, the resistance value of the resistor decreases, and current that is applied to the first thermoelectric material unit is diverted to the second thermoelectric material unit through the resistor.

13. The thermoelectric module according to claim 11, wherein the resistor is a negative temperature coefficient (NTC) thermistor.
